(19) United States
(12) Patent Application Publication
(10) Pub. No.: US 2010/0156436 A1
(43) Pub. Date: Jun. 24, 2010

(54) INTEGRATED CIRCUIT AND NOISE MEASURING METHOD

(75) Inventor: Tomoyuki NAKAO, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/716,520

(22) Filed: Mar. 3, 2010

Related U.S. Application Data
(63) Continuation of application No. PCT/JP2007/000988, filed on Sep. 10, 2007.

(51) Int. Cl. G01R 27/28; H03K 3/00

(52) U.S. Cl. 324/612; 327/108

(57) ABSTRACT

An internal circuit generates a digital signal according to an electric signal received from outside, and outputs the digital signal to an output signal line. An output circuit sets a voltage value of the digital signal to a prescribed value. A drive signal input circuit inputs a drive signal received from outside through a drive signal input terminal to the output circuit, and drives the output circuit independent of the digital signal according to the drive signal.

### CROSS-REFERENCE TO RELATED APPLICATIONS

This application is a continuation application of International PCT Application No. PCT/JP2007/000988 which was filed on Sep. 10, 2007.

### FIELD

The embodiments discussed herein relate to an integrated circuit and a method of measuring noise of the integrated circuit.

### BACKGROUND

A cause of the emission of radio waves of electronic equipment is electromagnetic interference (EMI) noise by a clock driver circuit of a large-scale integrated circuit (LSI) loaded onto a printed circuit.

A clock frequency has been enhanced by a recent higher-speed LSI. When the clock frequency exceeds 10 MHz, the harmonic is easily radio-emitted. In an LSI, a clock frequency of 100 MHz or more is normally used, and an electronic wave is emitted from an LSI and a printed circuit.

FIG. 1 illustrates the EMI noise generated by the LSI loaded onto the printed circuit. An LSI 12 is loaded onto a printed circuit 11, and a switch 13 is connected to the LSI 12. When the LSI 12 is in operation, power supply pin noise 21 and 22, signal pin noise 23 and 24, and emitted noise 25 from an LSI package are generated.

FIG. 2 illustrates a conventional method of measuring the EMI noise of a power supply of an electronic device. An electronic device 32 includes a power supply terminal 41, a clock oscillation circuit 42, an external circuit 43, and an LSI 44. The LSI 44 includes an internal circuit 51 and output driver circuits 52 through 56. When the LSI 44 normally operates, the internal circuit 51 generates digital signals according to a clock signal from the clock oscillation circuit 42 and input signals from the external circuit 43, and the output driver circuits 52 through 56 output the voltage values of the digital signal while holding the values at prescribed values.

In this case, the power supply current provided from the power supply terminal 41 changes by ON/OFF operations of the output driver circuits 52 through 56, thereby generating EMI noise on the power supply terminal 41. Then, by a spectrum analyzer 31 measuring the level of the spectrum voltage of the noise waveform, the capability of reducing the EMI noise of the electronic device 32 is evaluated. The noise measuring procedure in this case is described below.

(1) A control program 45 for operating the LSI 44 is read from a personal computer (PC) 33 to the external circuit 43. The external circuit 43 operates at a command of the control program 45, and communicates digital signals with the internal circuit 51.

(2) After confirming the normal operation of the LSI 44, the measuring probe of the spectrum analyzer 31 is applied to the power supply terminal 41 to measure a spectrum voltage.

The patent document 1 listed below relates to a system of measuring the noise generated in a semiconductor device, and the patent document 2 relates to a digital noise generation circuit capable of quantitatively controlling the amount of generated noise.

Patent Document 1: Japanese Laid-open Patent Publication No. 2006-214987

Patent Document 2: Japanese Laid-open Patent Publication No. 2001-264394

### SUMMARY

According to an aspect of the embodiment, an integrated circuit includes an input terminal, an internal circuit, an output circuit, a drive signal input circuit, a drive signal input terminal, and a power supply line.

The input terminal receives an electric signal from outside. The internal circuit generates a digital signal according to the electric signal, and outputs the digital signal to an output signal line. The output circuit sets a voltage value of the digital signal to a prescribed value. The power supply line supplies power to the output circuit from a power supply terminal. The drive signal input terminal receives a drive signal from outside, and the drive signal input circuit inputs the drive signal to the output circuit, and drives the output circuit independent of the digital signal by using the drive signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates the generation of EMI noise;

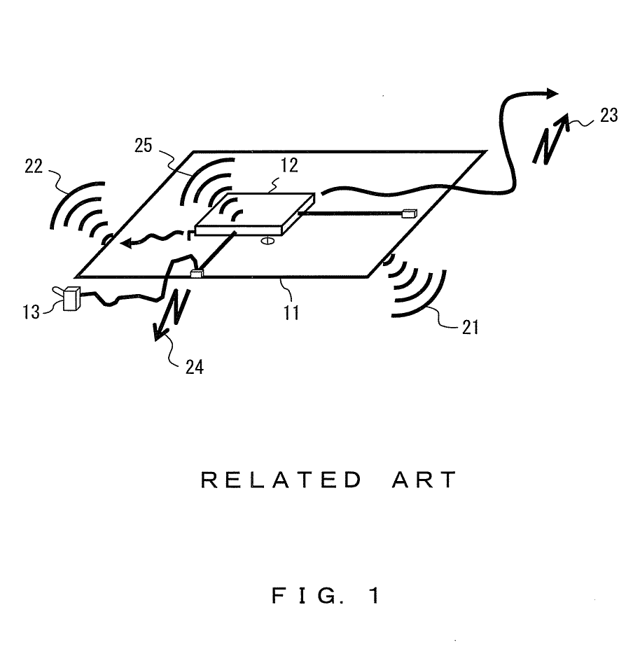

FIG. 2 illustrates a conventional noise measuring method;

FIG. 3 is a configuration diagram of an integrated circuit according to an embodiment;

FIG. 4 is a configuration diagram of the first LSI;

FIG. 5 is a configuration diagram of an output driver circuit;

FIG. 6 illustrates measuring noise of an LSI;

FIG. 7 is a configuration diagram of the second LSI;

FIG. 8 is a configuration diagram of the third LSI;

FIG. 9 is a configuration diagram of the fourth LSI;

FIG. 10 is a configuration diagram of the fifth LSI;

FIG. 11 illustrates measuring a noise spectrum;

FIG. 12 is a configuration diagram of the sixth LSI; and

FIG. 13 illustrates an LSI including a plurality of dies.

### DESCRIPTION OF EMBODIMENTS

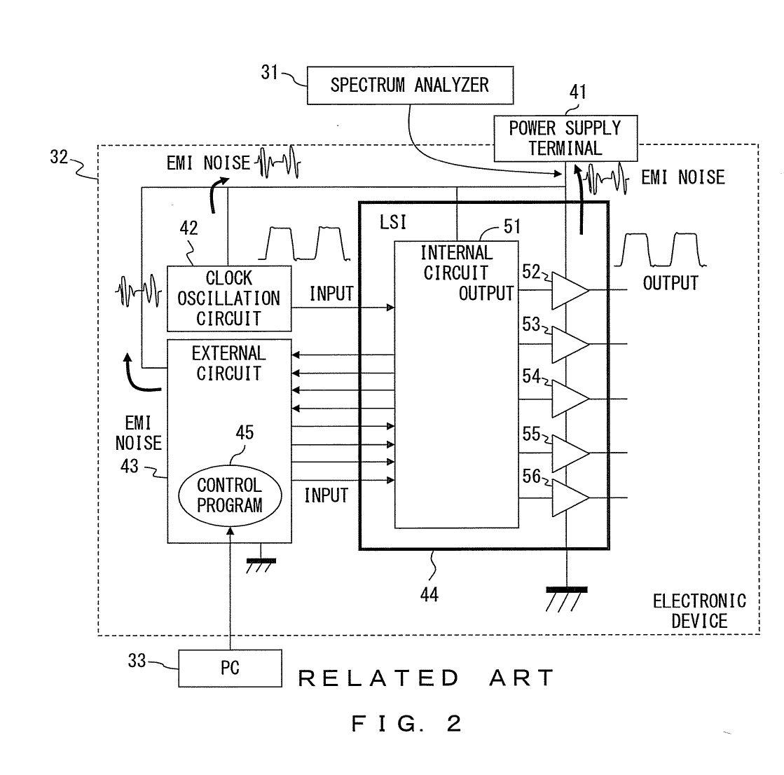

In the electronic device 32 illustrated in FIG. 2, when the evaluation of EMI noise is performed only for the LSI 44, it is considered that the configuration similar to that illustrated in FIG. 2 is used. In this case, there is the following problem.
Although the evaluation is performed only for the LSI 44, the clock oscillation circuit 42 and the external circuit 43 are required for operation of the LSI 44.
If the type of the LSI 44 is varied, dedicated circuit and substrate for the external circuit 43 are required, and a corresponding cost and number of process steps are demanded.
The evaluation accuracy is reduced by the generation of the EMI noise of the clock oscillation circuit 42 and the external circuit 43 in addition to the EMI noise of the LSI 44 to be evaluated.
It is necessary to read the control program 45 in advance.

It is considered that there occurs a similar problem when measuring noise of other integrated circuits in addition to the configuration illustrated in FIG. 2.

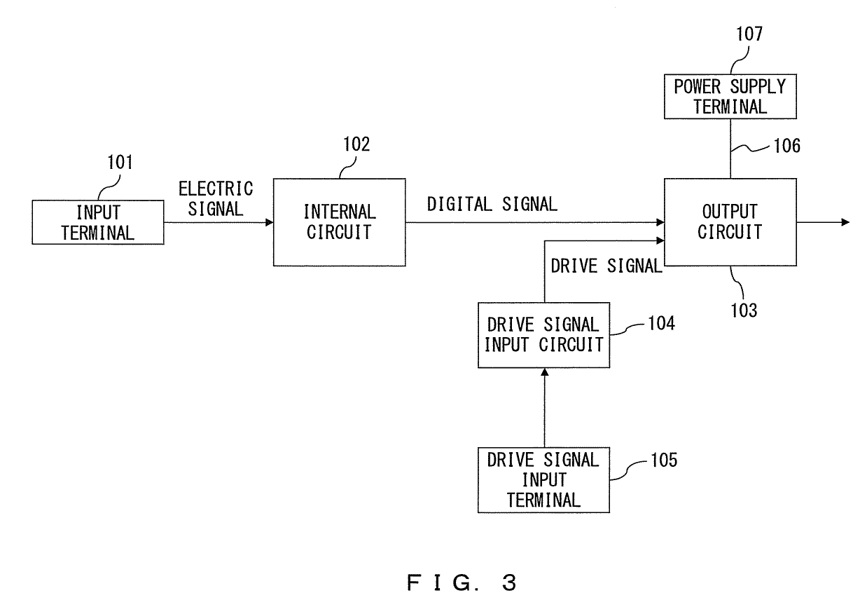

FIG. 3 is a configuration diagram of an integrated circuit according to an embodiment. The integrated circuit in FIG. 3 includes an input terminal 101, an internal circuit 102, an output circuit 103, a drive signal input circuit 104, a drive signal input terminal 105, and a power supply line 106.

The input terminal 101 receives an electric signal from outside. The internal circuit 102 generates a digital signal according to the electric signal, and outputs the digital signal to an output signal line. The output circuit 103 sets a voltage value of the digital signal to a prescribed value. The power supply line 106 supplies power to the output circuit 103 from a power supply terminal 107. The drive signal input terminal 105 receives a drive signal from outside, and the drive signal input circuit 104 inputs the drive signal to the output circuit 103, and drives the output circuit 103 independent of the digital signal by using the drive signal.

In the normal operation, the internal circuit 102 generates a digital signal according to the electric signal input from the input terminal 101, and outputs the digital signal to the output signal line through the output circuit 103. The voltage value of the digital signal output to the output signal line is held at the prescribed value by the output circuit 103.

When noise is measured, the internal circuit 102 is placed in an inoperative state. The drive signal input circuit 104 inputs the drive signal input from the drive signal input terminal 105 to the output circuit 103 to drive the output circuit 103. Thus, only the output circuit 103 operates to generate EMI noise.

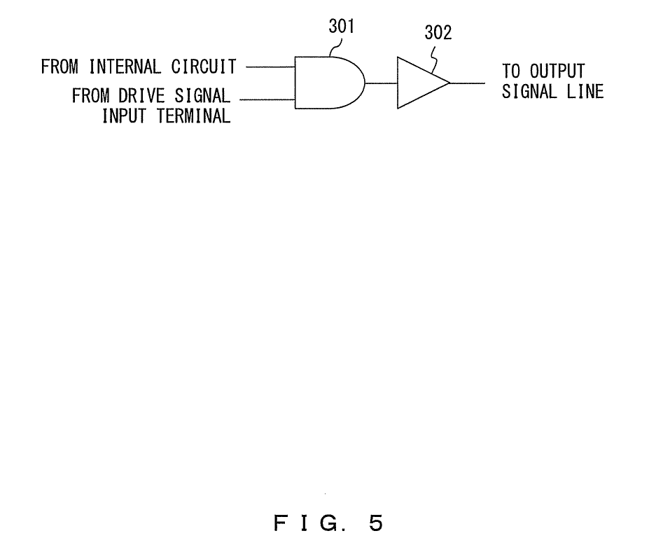

The output circuit 103 corresponds to, for example, a buffer circuit 302 in FIG. 5 described later, and the drive signal input circuit 104 corresponds to, for example, an AND circuit 301.

With the configuration illustrated in FIG. 3, if a circuit for inputting a drive signal is provided in an LSI, it is not necessary that an internal circuit operates for measuring noise. Therefore, the configuration of a device for evaluating noise can be simplified, thereby reducing the cost. In addition, since it is not necessary that the internal circuit operates, there is not EMI noise occurring from a peripheral circuit, and an accurate evaluation can be obtained.

As described above, since EMI noise can be measured with high accuracy at a low cost, the evaluation of an EMI design can be correctly performed on each LSI or electronic device. As a result, the device designer can select the LSI or the electronic device on the basis of the evaluation result of the EMI design, and design a device with reduced EMI noise.

The LSI according to the embodiment has the function of generating EMI noise without a normal operation. To be more concrete, a circuit for turning ON/OFF the output driver circuit as a main source of generating EMI noise is provided in addition to the functional circuit originally provided for the LSI.

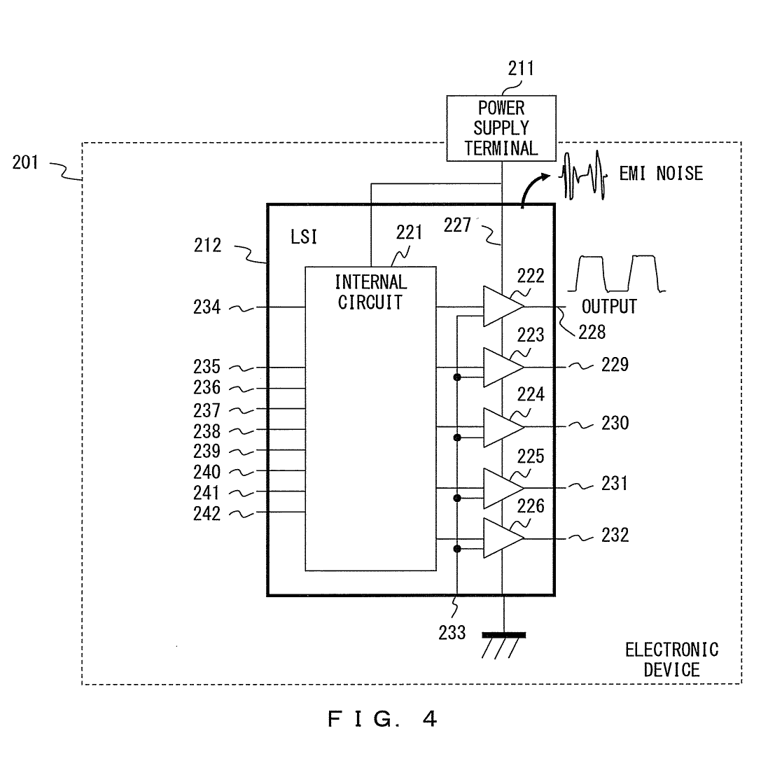

FIG. 4 illustrates an example of the configuration of the above-mentioned LSI. An electronic device 201 includes a power supply terminal 211 and an LSI 212, and the LSI 212 includes an internal circuit 221, output driver circuits 222 through 226, a power supply line 227, output signal lines 228 through 232, a drive signal input terminal 233, a clock signal input terminal 234, output terminals 235 through 238, and input terminals 239 through 242. The power supply line 227 provides power from the power supply terminal 211 to the output driver circuits 222 through 226.

In the normal operation, a clock signal is input to the clock signal input terminal 234, other signals are input to the input terminals 239 through 242, and a prescribed control signal is input to the drive signal input terminal 233. The internal circuit 221 generates a digital signal according to a signal input from the clock signal input terminal 234 and the input terminals 239 through 242, and outputs the digital signal to the output signal lines 228 through 232 through the output driver circuits 222 through 226.

The output driver circuits 222 through 226 includes, for example, the AND circuit 301 and the buffer circuit 302 as illustrated in FIG. 5. The AND circuit 301 outputs a logical product of the digital signal from the internal circuit 221 and the control signal from the drive signal input terminal 233, and the buffer circuit 302 holds the voltage value of the output signal of the AND circuit 301 at a prescribed value, and outputs the signal. In the normal operation, the digital signal from the internal circuit 221 can be output to the output signal line by inputting the control signal having the logic of “1” to the drive signal input terminal 233.

With the configuration in FIG. 4, five output driver circuits are provided. However, the number of output driver circuits provided is generally equal to the number of bits of output signals. For example, when the LSI generates a 32-bit output signal, 32 output driver circuits are provided.

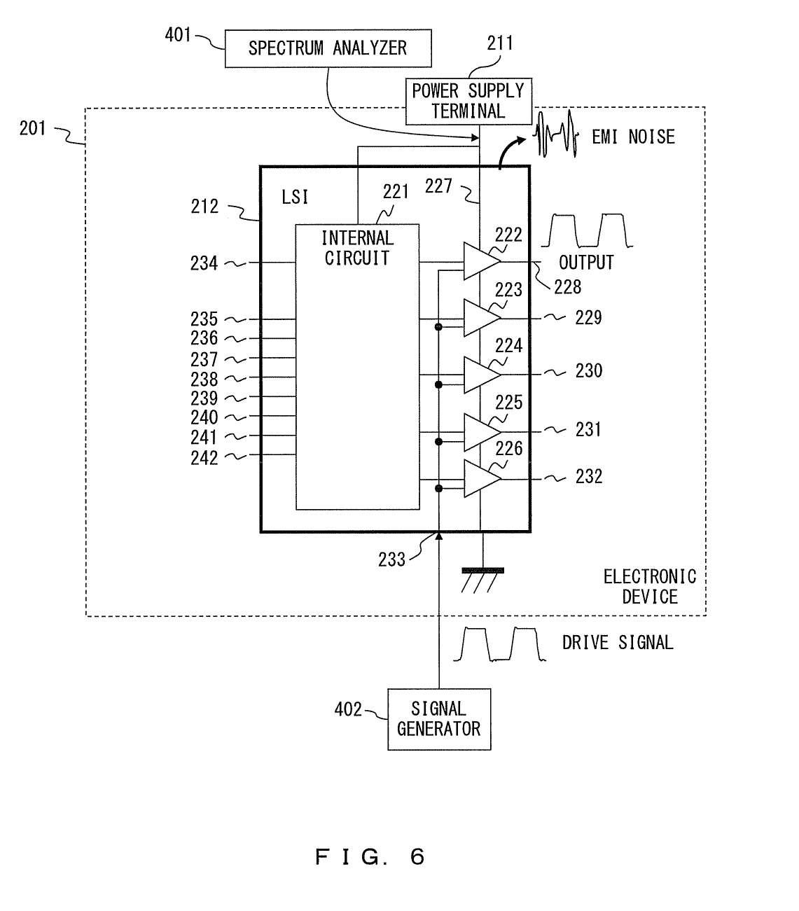

FIG. 6 illustrates the method of measuring the noise of the LSI illustrated in FIG. 4. When noise is measured, no power is supplied to the internal circuit 221, and power is supplied to the output driver circuits 222 through 226. A signal generator 402 is connected to the drive signal input terminal 233, and the drive signal generated by the signal generator 402 is input to the output driver circuits 222 through 226 through the drive signal input terminal 233. As the drive signal, for example, a signal at the same frequency as the clock signal in the normal operation is input.

In this case, the output signal of the internal circuit 221 is fixed to, for example, the logic of “1” by a pull-up circuit not illustrated in the attached drawings, and the AND circuit 301 illustrated in FIG. 5 outputs a drive signal from the drive signal input terminal 233 to the buffer circuit 302. Therefore, the buffer circuit 302 is driven by the drive signal in place of the output signal of the internal circuit 221.

Thus, by providing the AND circuit 301 at the input terminal of the buffer circuit 302, only the output driver circuits 222 through 226 can operate without the LSI 212 operating normally. Since the EMI noise is generated mainly by the ON/OFF operations of the buffer circuit 302, the EMI noise as in the normal operation can be generated in the power supply terminal 211 and the output signal lines 228 through 232 by driving the buffer circuit 302 at the frequency of the clock signal. The generated EMI noise is measured by a measurement unit such as a spectrum analyzer 401 etc.

With the configuration above, as compared with the conventional noise measuring method, the following effects can be acquired.
Since it is not necessary to provide the clock oscillation circuit and the external circuit required for normal operations of an LSI, an EMI noise evaluation can be realized at a low cost using a simple printed circuit for the evaluation.
Since it is not necessary to provide a control program for the normal operation of an LSI, the number of evaluating process steps can be reduced.
Since no EMI noise occurs from the clock oscillation circuit and the external circuit, a high-accuracy evaluation can be realized.

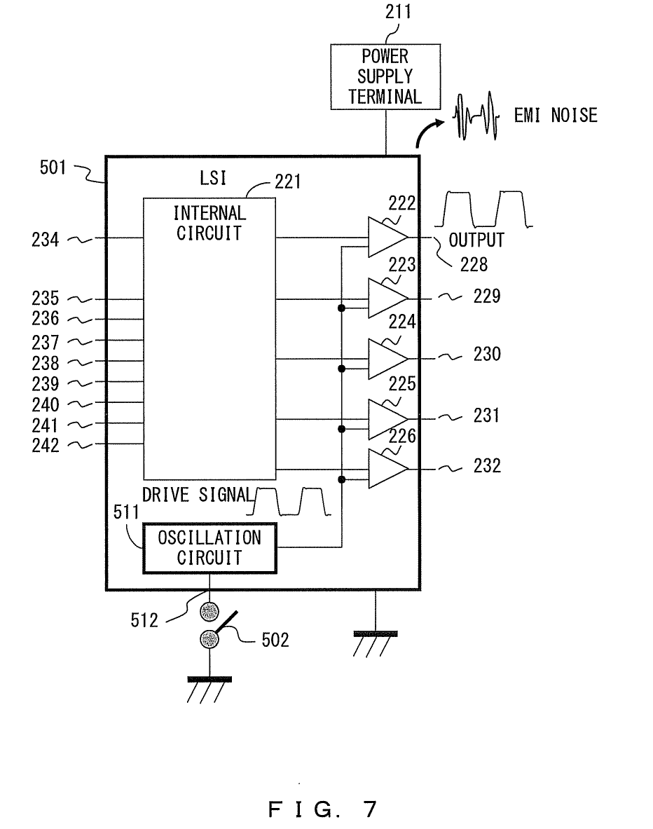

FIG. 7 illustrates an example of a configuration with which an oscillation circuit for generating a drive signal is built in an LSI. An LSI 501 includes an internal circuit 221, output driver circuits 222 through 226 output signal lines 228 through 232, a clock signal input terminal 234, output terminals 235 through 238, input terminals 239 through 242, an oscillation circuit 511, and an external terminal 512. Power is supplied from the power supply terminal 211 to the internal circuit 221, the output driver circuits 222 through 226, and the oscillation circuit 511 through the power supply line not illustrated in the attached drawings.

The oscillation circuit 511 is connected to the external terminal 512, and the external terminal 512 is connected to the ground through a switch 502. The oscillation circuit 511 operates when the switch 502 is turned ON, and stops when the switch 502 is turned OFF. Therefore, the external terminal 512 functions like the drive signal input terminal 233 illustrated in FIG. 6. An oscillation signal output from the oscillation circuit 511 is input as a drive signal to the output driver circuits 222 through 226.

When the switch 502 is turned ON and the oscillation circuit 511 operates with the power supply to the internal circuit 221 stopped, a drive signal is input to the output driver circuits 222 through 226. Thus, like in the case illustrated in FIG. 6, only the output driver circuits 222 through 226 operate, and the EMI noise occurs in the power supply terminal 211 and the output signal lines 228 through 232.

With the configuration, the signal generator 402 illustrated in FIG. 6 is unnecessary, and the EMI noise can be generated only by setting the switch 502.

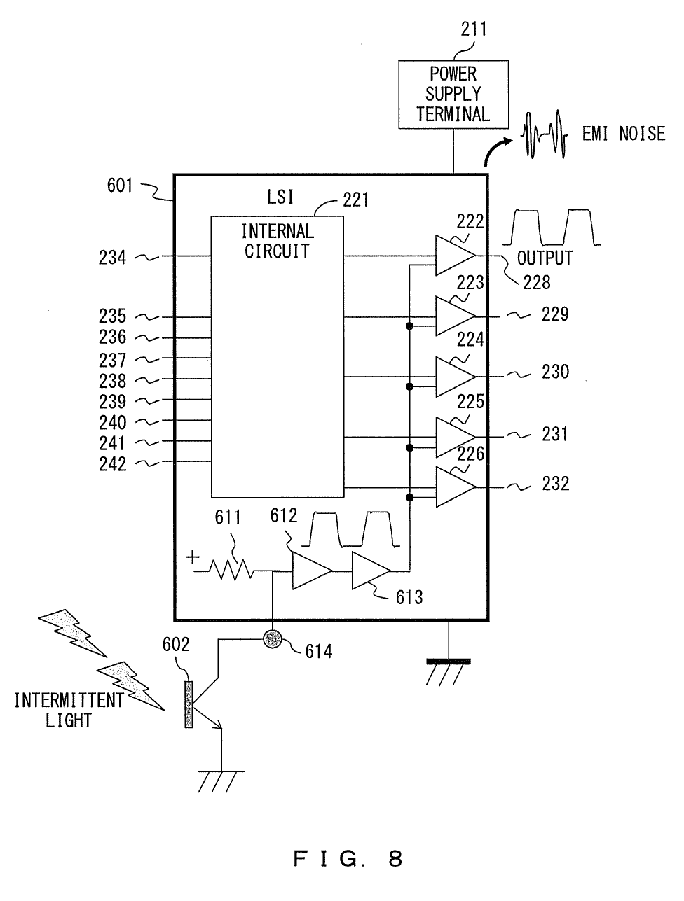

FIG. 8 illustrates an example of a configuration with which a drive signal is generated from an optical signal. An LSI 601 includes the internal circuit 221, the output driver circuits 222 through 226, the output signal lines 228 through 232, a clock signal input terminal 234, the output terminals 235 through 238, the input terminals 239 through 242, a pull-up resistor 611, amplification circuits 612 and 613, and a drive signal input terminal 614. Power is supplied from the power supply terminal 211 to the internal circuit 221, the output driver circuits 222 through 226, and the amplification circuits 612 and 613 through the power supply line not illustrated in the attached drawings.

A photosensor 602 such as a photo-transistor etc. is connected to the drive signal input terminal 614 to suppress the EMI noise. When intermittent light such as an infrared pulse etc. is emitted to the photosensor 602 with the power supply stopped to the internal circuit 221, the photosensor 602 converts the intermittent light into a pulse signal, and input the signal to the drive signal input terminal 614. The pulse signal is amplified by the amplification circuits 612 and 613 and input to the output driver circuits 222 through 226. Thus, only the output driver circuits 222 through 226 operate as in the case illustrated in FIG. 6, and the EMI noise occurs in the power supply terminal 211 and the output signal lines 228 through 232.

With the configuration, the electric signal as a drive signal is unnecessary, and the emission of radio waves thereby can be reduced. A pulse signal can replace the photosensor 602 to be connected to the drive signal input terminal 614.

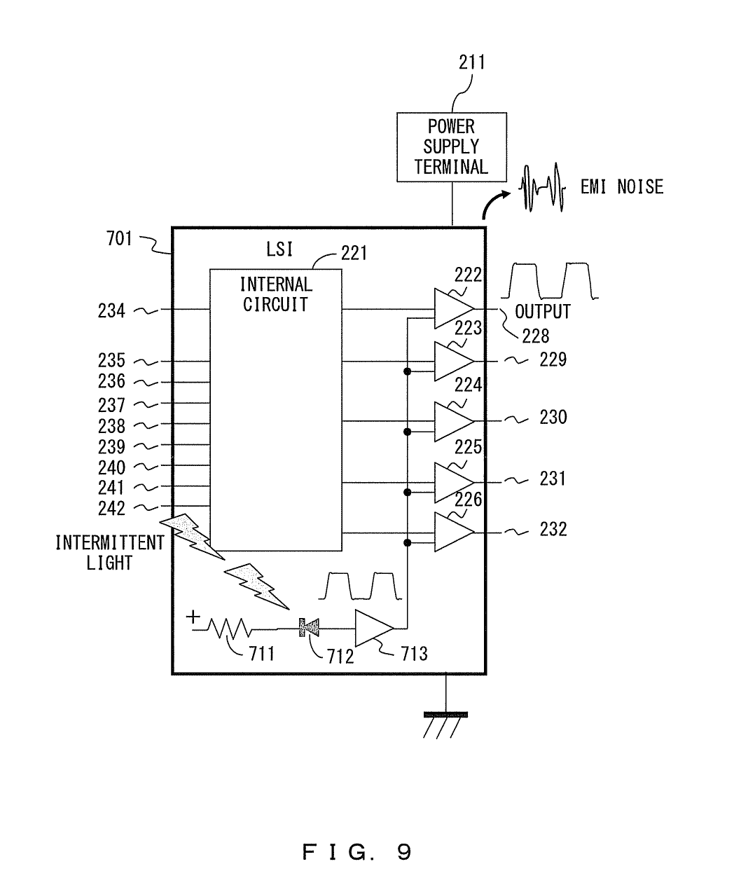

FIG. 9 illustrates an example of a configuration in which a photosensor for generating a drive signal is provided in an LSI package or chip. An LSI 701 includes the internal circuit 221, the output driver circuits 222 through 226, the output signal lines 228 through 232, the clock signal input terminal 234, the output terminals 235 through 238, the input terminals 239 through 242, a pull-up resistor 711, a photosensor 712, and an amplification circuit 713. Power is supplied from the power supply terminal 211 to the internal circuit 221, the output driver circuits 222 through 226, and the amplification circuit 713 through the power supply line not illustrated in the attached drawings.

In this case, a translucent material or a structure with a hole at the position of the photosensor 712 is applied to the package of the LSI 701 so that light can be emitted to the photosensor 712. The photosensor 712 can be, for example, a photodiode.

When intermittent light such as an infrared pulse etc. is emitted to the photosensor 712 with the power supply stopped to the internal circuit 221, a pulse signal is generated, and the pulse signal is amplified by the amplification circuit 713, and input to the output driver circuits 222 through 226. Thus, as in the case illustrated in FIG. 6, only the output driver circuits 222 through 226 operate, and the EMI noise is generated in the power supply terminal 211 and the output signal lines 228 through 232.

With the configuration, the external photosensor and the external terminal for connecting the photosensor are unnecessary by incorporating the photosensor into the LSI as a unitary construction.

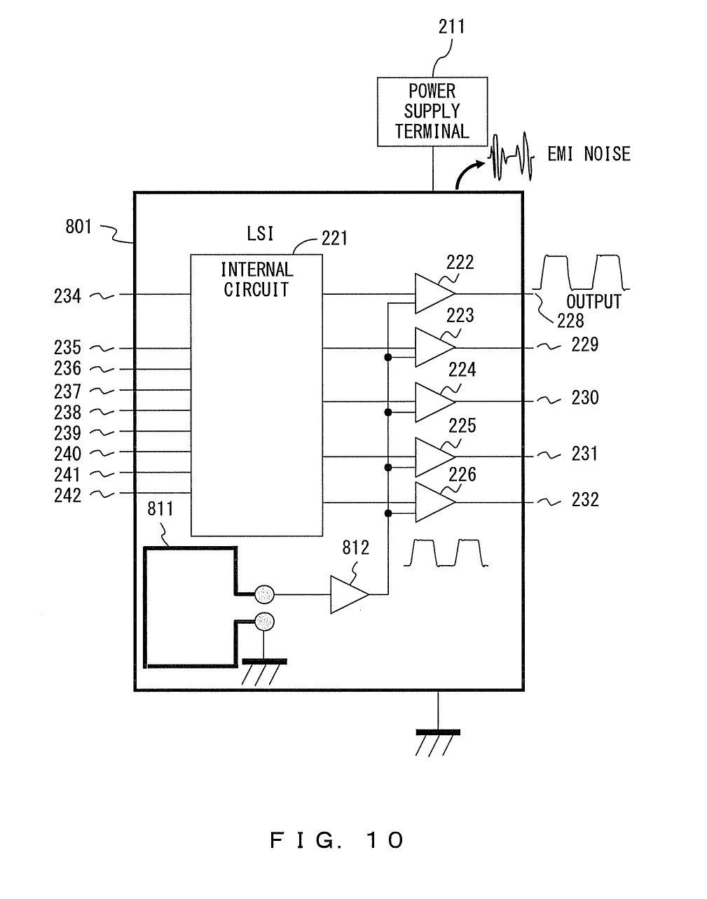

FIG. 10 illustrates an example of a configuration with which a drive signal is input as radio waves. An LSI 801 includes the internal circuit 221, the output driver circuits 222 through 226, the output signal lines 228 through 232, the clock signal input terminal 234, the output terminals 235 through 238, the input terminals 239 through 242, a loop antenna 811, and an amplification shaping circuit 812. Power is supplied from the power supply terminal 211 to the internal circuit 221, the output driver circuits 222 through 226, and the amplification shaping circuit 812 through the power supply line not illustrated in the attached drawings.

The loop antenna 811 is formed by a loop pattern in a chip or a pattern of a ball grid array (BGA) package.

When intermittent radio waves and magnetic field are emitted to the loop antenna 811 with the power supply to the internal circuit 221 stopped, the radio waves and magnetic field are received by the loop antenna 811, and a pulse signal is generated. The pulse signal is amplified and shaped by the amplification shaping circuit 812, and input to the output driver circuits 222 through 226. Thus, as in the case illustrated in FIG. 6, only the output driver circuits 222 through 226 operate, and the EMI noise is generated in the power supply terminal 211 and the output signal lines 228 through 232.

Since a normal mold can be used as the material of a package with the configuration above, the configuration can be realized at a cost lower than in the case illustrated in FIG. 9.

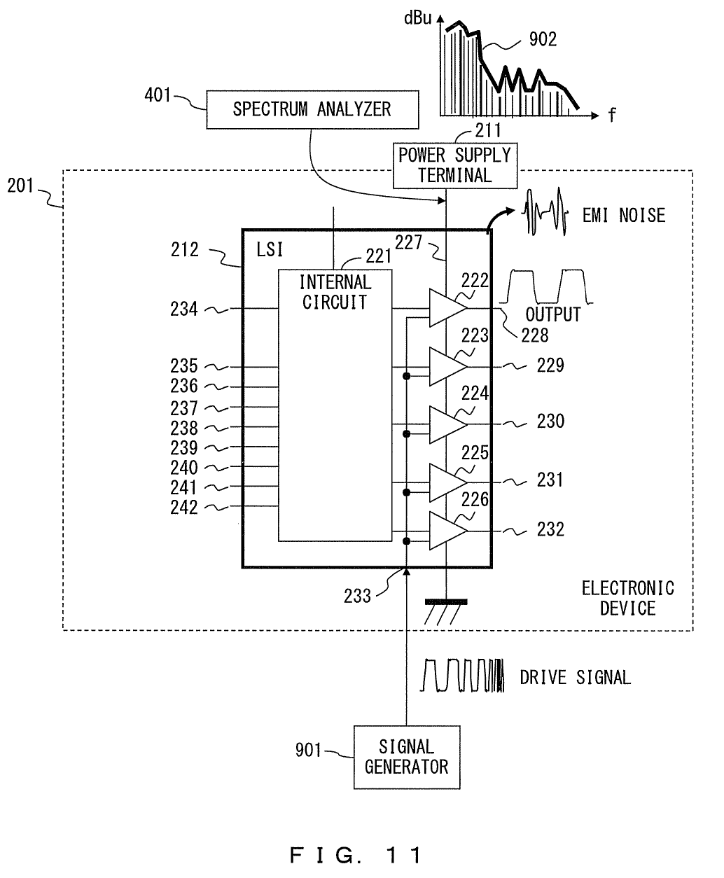

FIG. 11 illustrates a method of measuring a noise spectrum of EMI noise generated from the LSI 212 in FIG. 4.

When the noise is measured, a signal generator 901 is connected to the drive signal input terminal 233, and the frequency of the drive signal generated by the signal generator 901 is swept. In this case, for example, the frequency is scanned in the range of the frequency 10 through 100 MHz in which the output driver circuits 222 through 226 are operable.

Then, using the spectrum analyzer 401, the noise spectrum of the generated EMI noise is measured, and its envelope 902 is evaluated. If the EMI noise is measured by setting the spectrum analyzer 401 as maxhold, the noise components of all frequencies in the scanned range can be measured.

Although the operation frequency of a general-purpose LSI may depend on the design specifications of an electronic device, the noise reduction capability can be evaluated at any frequency in the above-mentioned noise measuring method.

With the configuration above, the same drive signal is input for all output driver circuits, but drive signals at different frequencies may be input to the output driver circuits.

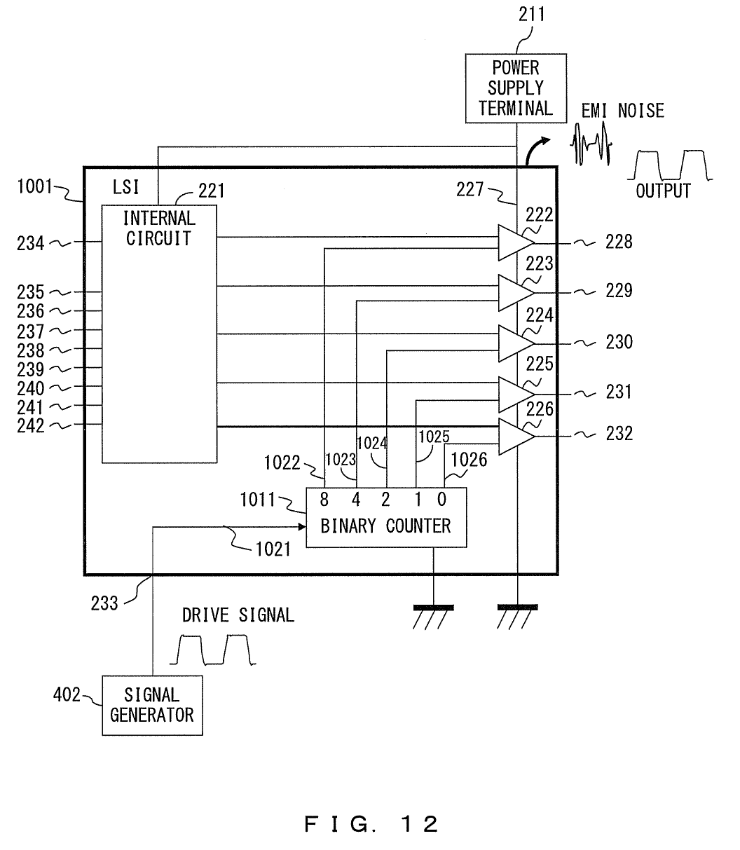

FIG. 12 illustrates an example of a configuration of the LSI. An LSI 1001 has a configuration of a binary counter 1011 provided between the drive signal input terminal 233 and the output driver circuits 222 through 226 in the LSI 212 in FIG. 4. In this case, power is also supplied from the power supply terminal 211 to the binary counter 1011 through the power supply line not illustrated in the attached drawings.

The drive signal input terminal 233 is connected to an input terminal 1021 of the binary counter 1011, and the output terminals 1022 through 1026 of the binary counter 1011 are respectively connected to the input terminals of the output driver circuits 222 through 226.

The signal generator 402 is connected to the drive signal input terminal 233 with the power supply to the internal circuit 221 stopped, and a drive signal is input to the binary counter 1011. In this case, the drive signals at the frequencies of 1/16, ⅛, ¼, ½, and 1/1 of the input signal are respectively output from the output terminals 1022 through 1026 of the binary counter 1011. Thus, the combinations of the timing of ON/OFF operations of the buffer circuit 302 in the output driver circuits 222 through 226 can be 2⁵=32 variations, thereby generating complicated EMI noise.

At least one of the output terminals 1022 through 1026 may be selectively connected to at least one of the output driver circuits 222 through 226 to generate the EMI noise in a part of the output driver circuits 222 through 226.

With the configuration illustrated in FIGS. 7 through 10, as with the configuration illustrated in FIG. 12, complicated EMI noise can be generated by providing the binary counter 1011 at the input terminals of the output driver circuits 222 through 226.

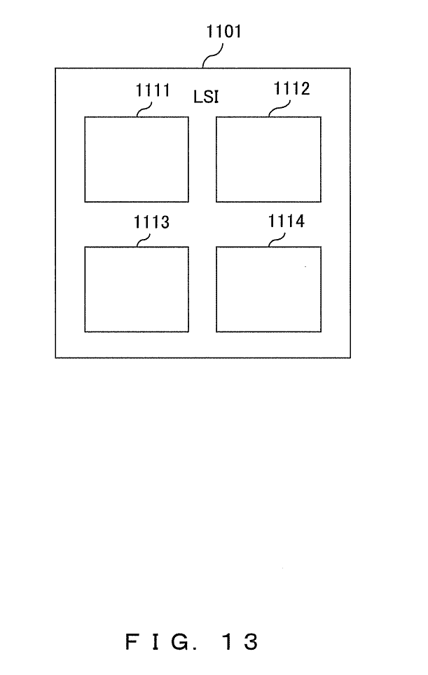

FIG. 13 illustrates an example of an LSI including a plurality of dies. An LSI 1101 includes dies 1111 through 1114, and each die includes a circuit like any of the LSIs illustrated in FIG. 4, FIGS. 7 through 10 and FIG. 12. For example, when each die includes the internal circuit 221 and the output driver circuits 222 through 226 illustrated in FIG. 4, a single power supply terminal provided for the LSI 1101 is connected to each die through a power supply line, and a drive signal is input to each die from a single drive signal input terminal.

The number of dies included in the LSI 1101 is not limited to four, but any number of dies may be provided.

All examples and conditional language recited herein are intended for pedagogical purposes to aid the reader in understanding the invention and the concepts contributed by the inventor to furthering the art, and are to be construed as being without limitation to such specifically recited examples and conditions, not does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An integrated circuit comprising:
an input terminal to receive an electric signal from outside;
an internal circuit to generate a digital signal according to the electric signal, and to output the digital signal to an output signal line;
an output circuit to set a voltage value of the digital signal to a prescribed value;
a power supply line to supply power to the output circuit from a power supply terminal;
a drive signal input terminal to receive a drive signal from outside; and
a circuit to input the drive signal to the output circuit, and to drive the output circuit independent of the digital signal by using the drive signal.

2. The integrated circuit according to claim 1, further comprising a counter provided between the drive signal input terminal and the output circuit, and the counter to input a drive signal to at least one output circuit of a plurality of output circuits according to the drive signal from outside.

3. The integrated circuit according to claim 1, further comprising
an oscillation circuit to convert the drive signal into an oscillation signal, and to input the oscillation signal to the output circuit.

4. The integrated circuit according to claim 1, wherein
the drive signal input terminal receives the drive signal as light.

5. The integrated circuit according to claim 1, wherein
the drive signal input terminal receives the drive signal as a radio wave.

6. The integrated circuit according to claim 1, wherein:
the integrated circuit comprises a plurality of dies;
each die includes the internal circuit and the output circuit;
the power supply terminal is connected to each of the plurality of dies through a power supply line; and
the drive signal is input from the drive signal input terminal to each of the plurality of dies.

7. An electronic device comprising:
an integrated circuit including:
an input terminal to receive an electric signal from outside;
an internal circuit to generate a digital signal according to the electric signal, and to output the digital signal to an output signal line;
an output circuit to set a voltage value of the digital signal to a prescribed value;
a power supply line to supply power to the output circuit from a power supply terminal;
a drive signal input terminal to receive a drive signal from outside; and
a circuit to input the drive signal to the output circuit, and to drive the output circuit independent of the digital signal by using the drive signal;
the external circuit; and
a power supply circuit to supply power to the integrated circuit and the external circuit.

8. The electronic device according to claim 7, wherein
the integrated circuit includes a counter provided between the drive signal input terminal and the output circuit, and the counter to input a drive signal to at least one output circuit of a plurality of output circuits according to the drive signal from outside.

9. The electronic device according to claim 7, further comprising
an optical signal reception unit to convert a received optical signal into the drive signal from outside, and to input the drive signal to the drive signal input terminal.

10. A method for measuring electromagnetic interference of an integrated circuit, the method comprising:
supplying power to an output circuit for setting a voltage value of a digital signal input from an internal circuit to a prescribed value, through a power supply terminal of the integrated circuit;
receiving a drive signal from outside by a drive signal input terminal of the integrated circuit;
inputting the drive signal to the output circuit independent of an input signal of the digital signal; and
measuring the electromagnetic interference occurring in the integrated circuit.

11. The method according to claim 10, wherein
a counter provided between the drive signal input terminal and the output circuit inputs the drive signal to at least one output circuit of a plurality of output circuits according to the drive signal from outside.
